(19) United States
(12) Patent Application Publication
(10) Pub. No.: US 2016/0073495 A1
(43) Pub. Date: Mar. 10, 2016

(54) METHOD FOR MANUFACTURING FLEXIBLE PRINTED CIRCUIT BOARD MODULE WITH REINFORCING BOARD, AND INTERMEDIATE STRUCTURE OF FLEXIBLE PRINTED CIRCUIT BOARD MODULE

(71) Applicant: KABUSHIKI KAISHA TOSHIBA, Tokyo (JP)

(72) Inventors: Akihiko HAPPOYA, Ome Tokyo (JP); Kota TOKUDA, Kawasaki Kanagawa (JP)

(21) Appl. No.: 14/636,751

(22) Filed: Mar. 3, 2015

(30) Foreign Application Priority Data
Sep. 9, 2014 (JP) 2014-183029

(51) Int. Cl. H05K 1/02; H05K 3/00

(52) U.S. Cl. CPC H05K 1/0281; H05K 3/0058; H05K 1/0296; H05K 1/0213; H05K 2201/09036

(57) ABSTRACT

A method for manufacturing a flexible printed circuit module, includes discharging an adhesive material from an inkjet head towards one or more target regions of a flexible printed circuit board, semi-curing the adhesive material on the flexible printed circuit board, placing one or more reinforcement members on a surface of the adhesive material, and pressing the one or more reinforcement members against the flexible printed circuit board while heating the adhesive material, such that the one or more reinforcement members are fixed on the flexible printed circuit board.

### CROSS-REFERENCE TO RELATED APPLICATION

This application is based upon and claims the benefit of priority from Japanese Patent Application No. 2014-183029, filed Sep. 9, 2014, the entire contents of which are incorporated herein by reference.

### FIELD

Embodiments described herein relate generally to a method for manufacturing a flexible printed circuit board module with a reinforcing board, and an intermediate structure of a flexible printed circuit board.

### BACKGROUND

A reinforcing board is often attached to a flexible printed circuit board for reinforcement. Such a reinforcing board is useful when parts such as switches or connectors are mounted on the flexible printed circuit board or the flexible printed circuit board is mounted to another device. In the related art, a reinforcing board is attached to the flexible printed circuit board with an adhesive film or a sheet. That is, an adhesive film or sheet that has a predetermined shape is first disposed in a predetermined position of a flexible printed circuit board using a positioning pin, and then a reinforcing board is disposed on the adhesive sheet using the positioning pin. Finally, the reinforcing board is pressed against the flexible printed circuit board while heating the adhesive film or sheet.

### DESCRIPTION OF THE DRAWINGS

FIG. 1A to 1C are cross-sectional views schematically illustrating a flexible printed circuit board having a reinforcing board according to a first embodiment.

FIG. 2 is a cross-sectional view schematically illustrating a flexible printed circuit board having a reinforcing board according to a second embodiment.

FIG. 3 is a cross-sectional view schematically illustrating a flexible printed circuit board having a reinforcing board according to a third embodiment.

FIG. 4 is a cross-sectional view schematically illustrating a flexible printed circuit board having a reinforcing board according to a fourth embodiment.

FIG. 5 is a cross-sectional view schematically illustrating a flexible printed circuit board having a reinforcing board according to a fifth embodiment.

FIG. 6 is a cross-sectional view schematically illustrating a flexible printed circuit board having a reinforcing board according to a sixth embodiment.

FIG. 7 is a perspective view of an electronic unit according to a seventh embodiment.

FIG. 8 is a perspective view of a module according to the seventh embodiment.

FIG. 9 is a cross-sectional view of a printed circuit board according to the seventh embodiment.

FIG. 10 is a plan view of the board according to the seventh embodiment.

FIG. 11 is a cross-sectional view of a cross-section XI-XI of a conductive adhesive layer and an insulating adhesive layer illustrated in FIG. 9.

FIG. 12 is a cross-sectional view of a flexible printed circuit board having an adhesive layer having a non-flat side surface.

### DETAILED DESCRIPTION

One or more embodiments are directed to provide a method for manufacturing a flexible printed circuit board with a reinforcing board more easily and efficiently.

In general, according to one embodiment, a method for manufacturing a flexible printed circuit module, includes discharging an adhesive material from an inkjet head towards one or more target regions of a flexible printed circuit board, semi-curing the adhesive material on the flexible printed circuit board, placing one or more reinforcement members on a surface of the adhesive material, and pressing the one or more reinforcement members against the flexible printed circuit board while heating the adhesive material, such that the one or more reinforcement members are fixed on the flexible printed circuit board.

Embodiments will be described with reference to the drawings.

This disclosure describes some components using different names. The names are only examples and these components may be represented by other names. Components not represented by different names may also be represented by other names.

In addition, since the drawings are illustrated schematically, the relationship between the thickness, the planar size and the ratio between the thicknesses of layers, and the like maybe different from the actual ones. In addition, parts having a different relationship of sizes or a different ratio of sizes between drawings may be included.

### First Embodiment

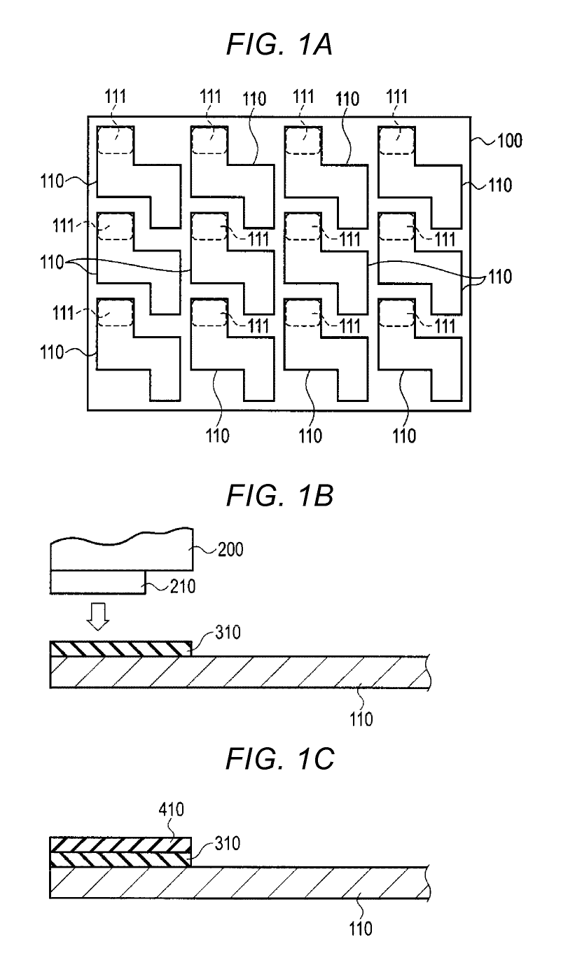

FIG. 1A to 1C are cross-sectional views of a flexible printed circuit (FPC) according to a first embodiment for explaining a manufacturing method.

First, a working panel 100 that defines and includes a plurality of FPCs 110 immediately before reinforcing boards are mounted is prepared in a usual manner (FIG. 1A). The FPCs 110 are reinforced by the reinforcing boards and the reinforcing boards are attached to reinforcement target portions 111 of the FPCs 110. An example of the FPC includes a wiring pattern provided on a flexible base film (board or base material) made of polyimide or the like by etching conductive foil such as copper foil. A cover film (normally, a polyimide film) of an insulating film is laminated on the wiring pattern through an adhesive. The wiring pattern may be formed on one side or both sides of the base film.

Next, an adhesive is applied to the reinforcement target portion 111 (see FIG. 1A) of the FPC 110 using an ink jet printing system. In the present embodiment and the embodiments described below, the application of an adhesive using the ink jet printing system includes ejecting and applying of an adhesive to the reinforcement target portion from the inkjet head using an ink jet apparatus. That is, as illustrated in FIG. 1B, an insulating adhesive is ejected and applied as indicated by the arrow from an ink jet head 210 using the ink jet apparatus 200 to the reinforcement target portion 111 (see FIG. 1A) of the FPC 110. This creates a layer 310 of the insulating adhesive before being cured. At this time, no mask is required. An epoxy, acrylic, or urethane adhesive may be used as the insulating adhesive.

Next, the insulating adhesive layer 310 is semi-cured, an insulating reinforcing board 400 is disposed thereon, and a reinforcing board 410 is pressed against the adhesive layer 310 under heating, to cure the adhesive, and, through the cured adhesive. As a result, the FPC 110 and the reinforcing board 410 are firmly bonded together. The insulating reinforcing board 410 to be used may be made of polyimide, polyethylene terephthalate (PET), liquid crystal polymer (LCP), glass epoxy, or the like.

Since the insulating adhesive used here has a thermosetting property as described above, the insulating adhesive normally includes a thermosetting agent.

In addition, the adhesive layer has substantially the same planar shape as the plane (that is, the surface in contact with the adhesive layer) of the reinforcing board to be disposed later (the same in the following embodiments).

### Second Embodiment

A second embodiment is the same as the first embodiment except that the second embodiment uses a conductive adhesive and a conductive reinforcing board.

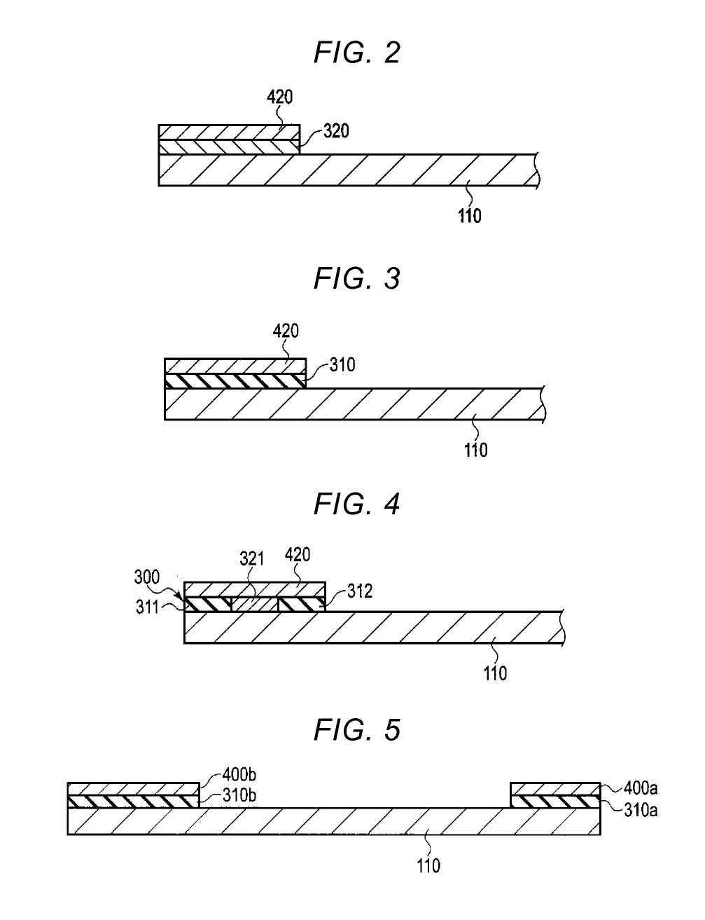

That is, referring to FIG. 2, a conductive adhesive is ejected from the ink jet head to the reinforcement target portion 111 (see FIG. 1A) of the FPC 110 using the ink jet apparatus, and a layer 320 of the conductive adhesive is formed. Silver paste, copper paste, or an epoxy, acrylic, or urethane adhesive including conductive particles may be used as the conductive adhesive.

Next, the conductive adhesive layer 320 is semi-cured, a conductive reinforcing board 420 is disposed thereon, and the reinforcing board 420 is pressed against the adhesive layer 320 under heating, to cure the adhesive, and, through the cured adhesive. As a result, the FPC 110 and the reinforcing board 420 are firmly bonded together. The conductive reinforcing board 420 to be used may be made of copper, aluminum, SUS, or the like.

Also in this case, since the conductive adhesive has a thermosetting property, the conductive adhesive includes a thermosetting agent.

Since the reinforcing board is conductive in the present embodiment, electrical connection to the ground pattern of the FPC is effective in noise reduction such as electromagnetic interference (EMI) reduction and in heat radiation of the heating component mounted on the FPC.

### Third Embodiment

A third embodiment is the same as the first embodiment except that the third embodiment uses an insulating adhesive and a conductive reinforcing board.

That is, referring to FIG. 3, an insulating adhesive is ejected from the ink jet head to the reinforcement target portion 111 (see FIG. 1A) of the FPC 110 using the ink jet apparatus, and the insulating adhesive layer 310 is formed. The insulating adhesive used in the first embodiment may be used as this insulating adhesive.

Next, the insulating adhesive layer 310 is semi-cured, the conductive reinforcing board 420 is disposed thereon, and the reinforcing board 420 is pressed against the adhesive layer 310 under heating, to cure the adhesive, and, through the cured adhesive. As a result, the FPC 110 and the reinforcing board 420 are firmly bonded. The conductive reinforcing board 420 used in the second embodiment may be used as the conductive reinforcing board 420 in the present embodiment.

Since the reinforcing board is conductive and the adhesive is insulating in the embodiment, heat of the heating component mounted on the FPC is effectively radiated.

### Fourth Embodiment

A fourth embodiment is the same as the first embodiment except that the adhesive layer includes a portion including an insulating adhesive and a portion including a conductive adhesive adjacent to the portion including an insulating adhesive, and uses a conductive reinforcing board.

That is, referring to FIG. 4, an insulating adhesive is ejected from the ink jet head to the reinforcement target portion 111 (see FIG. 1A) of the FPC 110 using the ink jet apparatus, and a first insulating adhesive layer part 311 is formed. Then a conductive adhesive is ejected from the ink jet head using the inkjet apparatus, and a conductive adhesive layer part 321 is formed in a position adjacent to the first insulating adhesive layer part 311. Finally, an insulating adhesive is ejected from the ink jet head using the ink jet apparatus, and a second insulating adhesive layer part 312 is formed in a position adjacent to the conductive adhesive layer part 321. The insulating adhesive used in the first embodiment maybe used as the insulating adhesive in the present embodiment, and the conductive adhesive used in the second embodiment may be used as the conductive adhesive in the present embodiment.

Next, an adhesive layer 300 including insulating adhesive layer parts 311 and 312 and the conductive adhesive layer part 321 is semi-cured, the conductive reinforcing board 420 is disposed thereon, and the reinforcing board 420 is pressed against the adhesive layer 300 under heating, to cure the adhesive, and, through the cured adhesive. As a result, the FPC 110 and the reinforcing board 420 are firmly bonded. The conductive reinforcing board 420 used in the second embodiment may be used as this conductive reinforcing board 420.

In the embodiment, since the reinforcing board is conductive, electrical connection to the ground pattern of the FPC achieves noise reduction such as electromagnetic interference (EMI) reduction. In the part of insulating adhesive, wiring with an electric potential different from that of the ground may be disposed on the surface of the FPC.

### Fifth Embodiment

According to a fifth embodiment, the FPC is reinforced at a plurality of positions. Further, the FPC according to the fifth embodiment includes a plurality of reinforcing boards, and the adhesive layers with which the reinforcing boards and the FPC are bonded together have different thicknesses.

That is, referring to FIG. 5, the FPC 110 includes two reinforcement target portions. An adhesive (for example, an insulating adhesive) with different thicknesses is ejected to the reinforcement target portions from an ink jet head using the ink jet apparatus to form insulating adhesive layers 310a and 310b with different thicknesses, respectively. In this case, the adhesive layer 310b is thicker than the adhesive 310a. The insulating adhesive used in the first embodiment may be used as the insulating adhesive in the present embodiment.

Next, the insulating adhesive layers 310a and 310b are semi-cured, reinforcing boards 400a and 400b are disposed on these layers, and the reinforcing boards 400a and 400b are pressed against the adhesive layers 310a and the 310b under heating, to cure the adhesive, and, through the adhesives. As a result, the FPC 110 and the reinforcing boards 400a and 400b are firmly bonded.

That is, in the present embodiment, the flexible printed circuit board includes the first and second reinforcement target portions and the first and second reinforcing boards are bonded to the flexible printed circuit board in the first and second reinforcement target portions through the adhesive layers with different thicknesses.

One example in which adhesive layers with different thicknesses are preferable to be formed as described above is the case in which one reinforcing board has an area larger than that of the other reinforcing board. Since a layer with a larger area is likely to warp, a thicker adhesive layer is required to absorb the warpage. The flexible printed circuit board with a reinforcing board manufactured in this case includes the flexible circuit board, the first reinforcing board bonded to the flexible circuit board through the first adhesive layer, and the second reinforcing board bonded to the flexible circuit board through the second adhesive layer, and the second reinforcing board has an area larger than that of the first reinforcing board and the second adhesive layer is thicker than the first adhesive layer.

Another example in which adhesive layers with different thicknesses are preferable to be formed is the case in which one reinforcing board has surface roughness smaller than that of the other reinforcing board. Since a reinforcing board with smaller surface roughness such as a metal plate is not easily bonded, a thicker adhesive layer is preferred. A reinforcing board made of synthetic resin is an example of a reinforcing board with large surface roughness. The flexible printed circuit board with a reinforcing board manufactured in this case includes the flexible circuit board, the first reinforcing board bonded to the flexible circuit board through the first adhesive layer, and the second reinforcing board bonded to the flexible circuit board through the second adhesive layer, and the second reinforcing board has surface roughness smaller than that of the first reinforcing board and the second adhesive layer is thicker than the first adhesive layer.

An ink jet printing system may be used to easily form adhesive layers with different thicknesses on a single FPC.

### Sixth Embodiment

In the sixth embodiment, the FPC includes a step section including an inclined plane and a three-dimensional shaped reinforcing board including a step section corresponding to the step section of the FPC is bonded to the step section of the FPC.

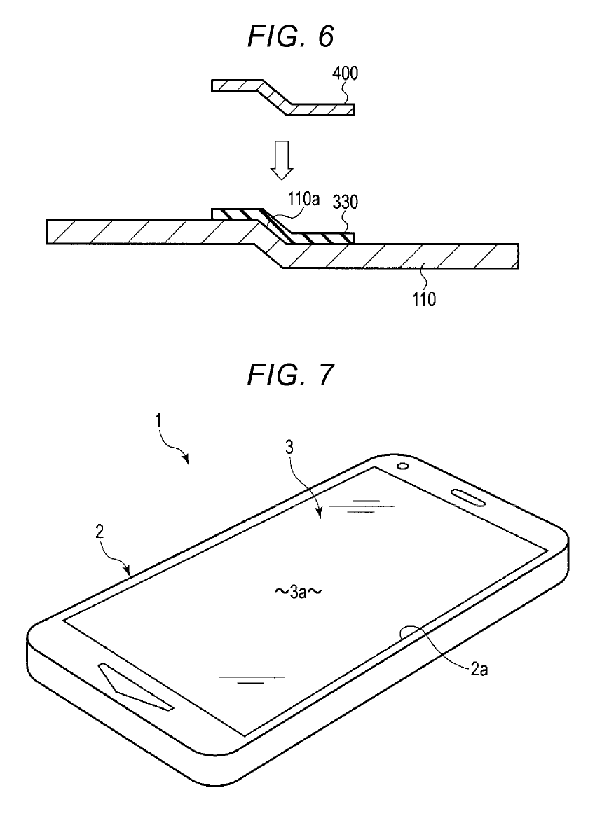

That is, with referring to FIG. 6, the FPC 110 includes a step portion including an inclined plane 110a. An adhesive (for example, an insulating adhesive) is ejected from the ink jet head to the step portion using the ink jet apparatus, and an insulating adhesive layer 330 is formed. The adhesive layer 330 has a uniform thickness along the shape of the step portion of the FPC 110. The insulating adhesive used in the first embodiment maybe used as the insulating adhesive in the present embodiment.

Next, the adhesive layer 330 is semi-cured, the reinforcing board 400 is disposed on the semi-cured adhesive layer 300, and the reinforcing board 400 is pressed against the adhesive layer 330 under heating, to cure the adhesive, and, through the adhesive. As a result, the FPC 110 and the reinforcing board 400 are firmly bonded together. The reinforcing board 400 includes a step portion corresponding to the step portion of the FPC 110.

An ink jet printing system may be used to easily apply an adhesive to a three-dimensional shaped portion of the FPC with such a three-dimensional shape.

### Seventh Embodiment

FIG. 7 illustrates an electronic unit 1 according to a seventh embodiment. The electronic unit 1 is, but not limited to, a mobile phone (smart phone), for example. The electronic unit 1 may be widely applied to, for example, electronic units such as a portable computer, a smart device (for example, tablet terminal), a video display apparatus (for example, television receiver), and a game machine.

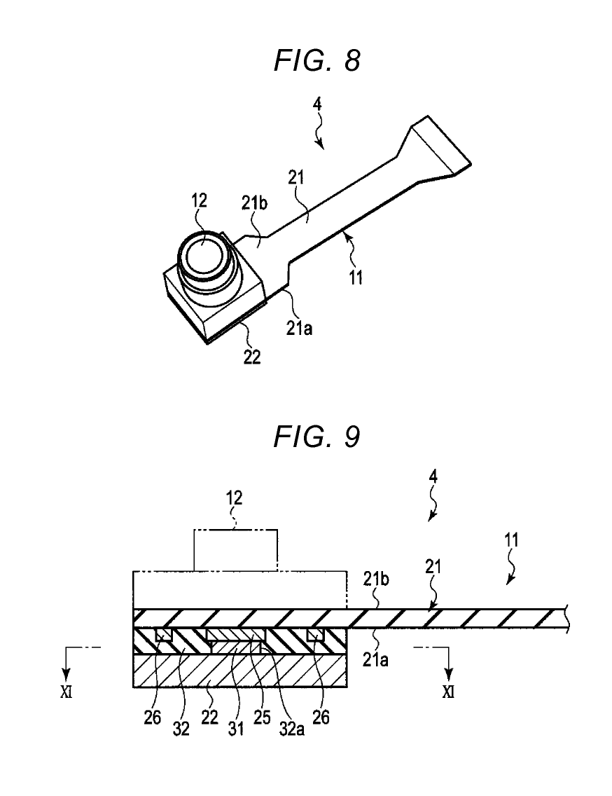

As illustrated in FIG. 7, the electronic unit 1 includes a housing 2 (case), a display apparatus 3 accommodated in the housing 2, and a module 4 (see FIG. 8) accommodated in the housing 2. The housing 2 includes an opening 2a through which a display screen 3a of the display apparatus 3 is exposed. The opening 2a is covered with, for example, a transparent protective panel (for example, glass panel or plastic panel).

FIG. 8 illustrates the module 4 according to the embodiment. The module 4 according to the embodiment is, for example, a camera module. The module 4 is not limited to this and may be various modules including an FPC such as, for example, various types of connector modules, as appropriate.

As illustrated in FIG. 8, the module 4 includes the FPC 11 and the camera 12. The camera 12 is an example of functional components included in the module 4. The camera 12 is mounted to an end of the printed circuit board 11 and electrically connected to the FPC 11.

FIG. 9 illustrates the FPC 11 according to the embodiment. The FPC 11 includes a flexible board 21 (base material or film) and a conductive reinforcing board 22 mounted on a part (for example, an end) of the board 21. The board 21 is, for example, a four-layer board or two-layer board and includes a wiring pattern on an internal layer thereof. The board 21 includes a first plane 21a and a second plane 21b positioned on a side opposite to the first plane 21a. The camera 12 is mounted on the second plane 21b.

As illustrated in FIG. 9, a ground pattern 25 and a wiring pattern 26 (wiring) are provided on the first plane 21a (surface) of the board 21. The wiring pattern 26 is a wiring pattern (signal wiring) through which, for example, a signal is transmitted. The wiring pattern 26 may be a wiring pattern (power source wiring) through which power is supplied.

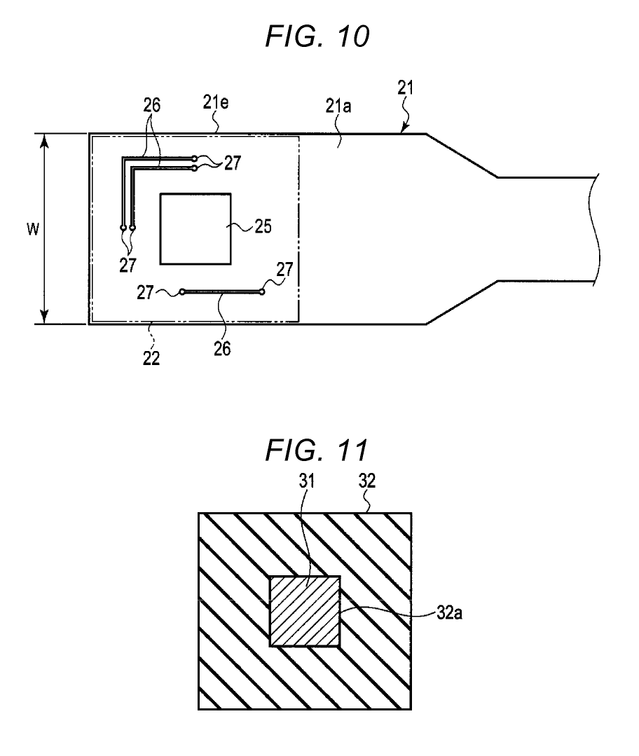

FIG. 10 is a plan view of the first plane 21a of the board 21. The ground pattern 25 is a solid layer with a predetermined area and has, for example, a rectangular shape. The ground pattern 25 is provided across a part of the width W of the board 21. That is, the ground pattern 25 is away from an edge 21e of the board 21. A plurality of wiring patterns 26 and vias 27 are provided between the ground pattern 25 and the edge 21e of the board 21.

As illustrated in FIG. 9, the reinforcing board 22 faces the first plane 21a of board 21. The reinforcing board 22 is located, for example, at a region corresponding to the camera 12. If the reinforcing board 22 is provided, the flatness and strength of the board 21 is improved in an area in which the camera 12 is mounted. This improves the imaging quality of the camera 12 and the impact resistance and the like of the camera 12 and the board 21.

As illustrated in FIG. 9 and FIG. 10, the reinforcing board 22 has a size large enough to totally cover the ground pattern 25 and a plurality of wiring patterns 26 and vias 27. The reinforcing board 22 has a width substantially the same as, for example, the width W of the board 21. The reinforcing board 22 is, for example, a metal plate or made of, for example, stainless steel (SUS). The reinforcing board 22 may be made of non-metal material as long as it is conductive, and may be a member made of, for example, synthetic resin having a conductivity layer on its surface by plating or the like.

As illustrated in FIG. 9, in the embodiment, a conductive adhesive layer 31 is provided between the reinforcing board 22 and the ground pattern 25. The conductive adhesive layer 31 bonds the center of the reinforcing board 22 and the ground pattern 25 (that is, bonds the reinforcing board 22 and the board 21) and electrically connects the reinforcing board 22 and the ground pattern 25.

As a result, the reinforcing board 22 has the ground electric potential and functions as a shield member for EMI prevention. In addition, the reinforcing board 22 is thermally connected to the board 21 through the conductive adhesive layer 31 and the ground pattern 25. As a result, the reinforcing board 22 made of metal functions as a radiating member for the board 21.

On the other hand, an insulating adhesive layer 32 (nonconductive adhesive layer) is provided between the reinforcing board 22 and the wiring pattern 26. The insulating adhesive layer 32 bonds the reinforcing board 22 and the first plane 21a of the board 21 together and insulates the reinforcing board 22 from the wiring pattern 26. This prevents a short circuit between the wiring pattern 26 and the conductive reinforcing board 22.

FIG. 11 is a cross-sectional view of the conductive adhesive layer 31 and the insulating adhesive layer 32. The insulating adhesive layer 32 is formed like a frame (that is, a frame surrounding the ground pattern 25) surrounding the conductive adhesive layer 31, and an opening 32a facing the ground pattern 25 is formed. The conductive adhesive layer 31 is provided within the frame-shaped insulating adhesive layer 32 (that is, within the opening 32a ) and exposed to both surfaces of the insulating adhesive layer 32.

Next, an exemplary method for manufacturing the FPC 11 will be described.

Referring to FIG. 9, an insulating adhesive is first ejected from the ink jet head to the reinforcement target portion on the first plane 21a of the board 21 using the ink jet apparatus to form the insulating adhesive layer 32. With this, the wiring pattern 26 and the via 27 are covered with the insulating adhesive layer 32. The opening 32a is provided in a part of the insulating adhesive layer 32 that faces the ground pattern 25.

Next, a conductive adhesive is similarly applied to the opening 32a of the insulating adhesive layer 32 using an ink jet printing system, and the conductive adhesive layer 31 is formed. Through this process, the conductive adhesive layer 31 contacts and is electrically connected to the ground pattern 25. Next, the insulating adhesive and the conductive adhesive are semi-cured, and the insulating adhesive layer 32 and the conductive adhesive layer 31 are disposed between the board 21 and the conductive reinforcing board 22 and then crimped by applying heat and pressure.

Through this process, the conductive reinforcing board 22 is bonded to the board 21 through the conductive adhesive layer 31 and electrically connected to the ground pattern 25 through the conductive adhesive layer 31. In addition, the conductive reinforcing board 22 is bonded to the board 21 through the insulating adhesive layer 32.

As a result, the printed circuit board 11 including the conductive reinforcing board 22 is provided. The insulating adhesive and the conductive adhesive have a thermosetting property, as described above.

The insulating adhesive layer 32 may be formed by applying an insulating adhesive to the first plane 21a of the board 21 instead of using the above manufacturing method.

In the printed circuit board 11 with such a structure, the wiring efficiency may be improved. That is, when the reinforcing board is mounted on the printed circuit board, the ground pattern with an area substantially the same as that of the shape of the reinforcing board is provided on the surface of the board, generally. In this case, since the ground pattern occupies a large area on the surface of the board, wiring patterns for power sources and signals cannot be disposed in the region. As a result, the number of layers and the size of the PFC are increased.

On the other hand, the FPC 11 according to the present embodiment includes the board 21, the ground pattern 25 provided on the board 21, the wiring pattern 26 provided on the board 21, the conductive reinforcing board 22, and the insulating adhesive layer 32. The conductive reinforcing board 22 covers the ground pattern 25 and the wiring pattern 26 and is electrically connected to the ground pattern 25. The insulating part is provided between the conductive reinforcing board 22 and the wiring pattern 26.

In such a structure, a part of the region on the surface of the board 21 covered with the conductive reinforcing board 22 may be used as a region in which the wiring pattern 26 and the via 27 are provided. This improves the wiring efficiency. In addition, the improvement of the wiring efficiency reduces the number of layers in the board 21, thereby achieving reduction in the thickness and the size of the printed circuit board 11.

In the embodiment, the insulating part provided between the conductive reinforcing board 22 and the wiring pattern 26 is the insulating adhesive layer 32. The insulating adhesive layer 32 bonds the conductive reinforcing board 22 and the board 21. In such a structure, even if the wiring pattern 26 is provided in the region covered with the conductive reinforcing board 22, the bonding force between the board 21 and the conductive reinforcing board 22 may be ensured sufficiently. This improves the reliability of the printed circuit board 11.

In the embodiment, the insulating adhesive layer 32 is formed like a frame surrounding the ground pattern 25. In such a structure, a relatively large area may be assigned to the region in which the wiring pattern 26 is provided and the bonding force between the board 21 and the conductive reinforcing board 22 may be ensured sufficiently. This further improves the wiring efficiency of the printed circuit board 11.

The embodiment further includes the conductive adhesive layer 31 provided between the conductive reinforcing board 22 and the ground pattern 25. The conductive adhesive layer 31 bonds the conductive reinforcing board 22 and the board 21. Such a structure further increases the bonding force between the board 21 and the conductive reinforcing board 22 and improves reliability of the printed circuit board 11.

In the embodiment, the insulating adhesive layer 32 is formed like a frame, and the opening 32a facing the ground pattern 25 is formed therein. The conductive adhesive layer 31 is provided within the opening 32a of the insulating adhesive layer 32. In such a structure, even if the insulating adhesive layer 32 is provided between the board 21 and the conductive reinforcing board 22, an electrical connection between the board 21 and the conductive reinforcing board 22 maybe ensured.

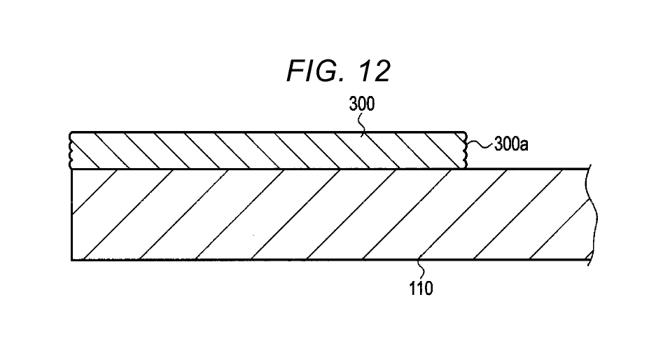

According to the first to seventh embodiments, the adhesive is applied to the reinforcement target portion of an FPC using an ink jet printing system. Accordingly, at least a part of a surface of the adhesive semi-cured after the adhesive is applied to the reinforcement target portion of the FPC reflects the contour of droplets ejected from the inkjet head. Here, “reflects the contour of droplets” represents not only the case in which the contour of droplets is the same as the surface shape of the adhesive, but also the case in which the contour of droplets is deformed due to their own weight, and it generally means that the surface of the adhesive layer is non-flat (wavy). It may be said that the flexible printed circuit board (intermediate) with such a semi-cured adhesive layer includes the flexible printed circuit board 110 including the reinforcement target portion and the semi-cured adhesive layer 300 applied to the reinforcement target portion, and at least a part of a surface 300a of the adhesive layer reflects the contour of droplets ejected from the ink jet head, as illustrated in FIG. 12. The non-flat surface includes, for example, the corrugated surface 300a illustrated in FIG. 12.

In the above embodiments, since an adhesive for bonding the FPC and the reinforcing board together is ejected and applied using an ink jet printing system, the number of processes maybe reduced and the accuracy of positioning during application of the adhesive becomes higher as compared with a bonding method using an adhesive sheet in the related art. In addition, when using an adhesive sheet, unnecessary parts generated due to die-cutting need to be discarded. However, since an adhesive is applied using an ink jet system in the above embodiments, no adhesive material is wasted and, if a failed FPC is present in the working panel, it is possible not to apply an adhesive to the failed FPC. In an ink jet system, three-dimensional reinforcing board, which cannot be achieved by an adhesive sheet, may also be used easily and the thickness of the adhesive may be partially changed easily.

Accordingly, according to one or more of the above embodiments, a flexible printed circuit board with a reinforcing board may be manufactured more easily and efficiency.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a flexible printed circuit module, comprising:
discharging an adhesive material from an inkjet head towards one or more target regions of a flexible printed circuit board;
semi-curing the adhesive material on the flexible printed circuit board;
placing one or more reinforcement members on a surface of the adhesive material; and
pressing the one or more reinforcement members against the flexible printed circuit board while heating the adhesive material, such that the one or more reinforcement members are fixed on the flexible printed circuit board.

2. The method according to claim 1, wherein the adhesive material is an insulating material and the reinforcement member is an insulating member.

3. The method according to claim 1, wherein the adhesive material is a conductive material and the reinforcement member is a conductive member.

4. The method according to claim 1, wherein the adhesive material is an insulating material and the reinforcement member is a conductive member.

5. The method according to claim 1, wherein
the flexible printed circuit board includes a bent portion, and
the target region includes the bent portion.

6. The method according to claim 5, wherein
the reinforcement member includes a bent portion that corresponds to the bent portion of the flexible printed circuit board.

7. The method according to claim 1, wherein
the one or more target regions includes a first target region and a second target region that is apart from the first target region, and
a thickness of the adhesive material on the first target region is greater than a thickness of the adhesive material on the second target region.

8. The method according to claim 7, wherein
an area of the adhesive material on the first target region is greater than an area of the adhesive material on the second target region.

9. The method according to claim 10, wherein
a roughness of the adhesive material on the first target region is greater than a roughness of the adhesive material on the second target region.

10. A method for manufacturing a flexible printed circuit module, comprising:
discharging an insulating adhesive material from an inkjet head towards a first target region of a flexible printed circuit board;
discharging a conductive adhesive material from an inkjet head towards a second target region of a flexible printed circuit board that is adjacent to the first target region;
semi-curing the insulating adhesive material and the conductive adhesive material on the flexible printed circuit board;
placing a reinforcement member on surfaces of the insulating adhesive material and the conductive adhesive material; and
pressing the reinforcement member against the flexible printed circuit board while heating the adhesive material, such that the reinforcement member is fixed on the flexible printed circuit board.

11. The method according to claim 10, wherein
the flexible printed circuit board includes a ground pattern and a wiring pattern thereon,
the conductive adhesive material is discharged on the ground pattern, and
the insulating adhesive material is discharged on the wiring pattern.

12. The method according to claim 11, wherein
the conductive adhesive material is surrounded by the insulating adhesive material.

13. The method according to claim 11, wherein
the ground pattern and the wiring pattern are formed on a first surface of the flexible printed circuit board, and
an image capturing unit is formed on a second surface of the flexible printed circuit board that is opposite to the first surface.

14. The method according to claim 13, wherein
a location of the image capturing unit corresponds to a location of the reinforcement member.

15. An intermediate structure of a flexible printed circuit board module, comprising:
a flexible printed circuit board; and
a semi-cured adhesive layer disposed on a surface portion of the flexible printed circuit board, wherein at least a peripheral surface of the semi-cured adhesive layer has a shape that includes a contour portion of a droplet.

16. The intermediate structure according to claim 15, wherein the shape includes a waved surface.

17. The intermediate structure according to claim 9, wherein
the flexible printed circuit board includes a ground pattern and a wiring pattern thereon, and
the semi-cured adhesive layer is disposed on the ground pattern and the wiring pattern.
